(19) United States
(12) Patent Application Publication
(10) Pub. No.: US 2026/0075818 A1
(43) Pub. Date: Mar. 12, 2026

(54) THREE-DIMENSIONAL MEMORY DEVICE WITH BACKSIDE GATE ELECTRODE AND METHODS OF FORMING THE SAME

(71) Applicant: Sandisk Technologies, Inc., Milpitas, CA (US)

(72) Inventors: Masanori TSUTSUMI, Yokkaichi (JP); Akio NISHIDA, Yokkaichi (JP)

(21) Appl. No.: 18/883,650

(22) Filed: Sep. 12, 2024

(51) Int. Cl. H10B 43/27; H01L 23/00; H01L 25/00; H01L 25/065; H01L 25/18; H10B 80/00

(52) U.S. Cl. CPC H10B 43/27; H10B 80/00; H10W 90/00; H10W 80/211; H10W 80/312; H10W 80/327; H10W 90/792

(57) ABSTRACT

A memory device includes an alternating stack of insulating layers and electrically conductive layers, a memory opening vertically extending through the alternating stack, a memory opening fill structure located in the memory opening and including a vertical stack of memory elements located at levels of the electrically conductive layers and a vertical semiconductor channel, a source layer contacting an outer sidewall of the vertical semiconductor channel, a backside gate electrode laterally surrounded by the vertical semiconductor channel and spaced from the vertical semiconductor channel by a backside gate dielectric layer, and a backside electrode contact layer in contact with the backside gate electrode and vertically spaced from the alternating stack by the source layer.

### FIELD

The present disclosure relates generally to the field of semiconductor devices, and particularly to a three-dimensional memory device including memory opening fill structures each including a respective backside gate electrode and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes an alternating stack of insulating layers and electrically conductive layers, a memory opening vertically extending through the alternating stack, a memory opening fill structure located in the memory opening and including a vertical stack of memory elements located at levels of the electrically conductive layers and a vertical semiconductor channel, a source layer contacting an outer sidewall of the vertical semiconductor channel, a backside gate electrode laterally surrounded by the vertical semiconductor channel and spaced from the vertical semiconductor channel by a backside gate dielectric layer, and a backside electrode contact layer in contact with the backside gate electrode and vertically spaced from the alternating stack by the source layer.

According to another aspect of the present disclosure, a method of forming a device structure comprises: forming a source-level sacrificial layer and an alternating stack of insulating layers and sacrificial material layers over a substrate; a memory opening through the alternating stack and the source-level sacrificial layer; forming a memory opening fill structure in the memory opening, wherein the memory opening fill structure comprises, from outside to inside and in an order of formation, a memory film, a vertical semiconductor channel, a backside gate dielectric layer; and a backside gate electrode; replacing the source-level sacrificial layer with a source contact layer such that the source contact layer contacts an outer sidewall of the vertical semiconductor channel; and replacing the sacrificial material layers with electrically conductive layers.

### BRIEF DESCRIPTION OF THE DRAWINGS

FIG. 1 is a schematic vertical cross-sectional view of an exemplary structure for forming a memory die after formation of a first stopper layer, a second stopper layer, a backside insulating layer, in-process source-level material layers, and an alternating stack of insulating layers and sacrificial material layers over a substrate according to an embodiment of the present disclosure.

FIG. 2 is a schematic vertical cross-sectional view of the exemplary structure after formation of stepped surfaces and a retro-stepped dielectric material portion according to an embodiment of the present disclosure.

FIG. 3A is a schematic vertical cross-sectional view of the exemplary structure after forming memory openings and support openings according to an embodiment of the present disclosure.

FIG. 3B is a top-down view of the exemplary structure of FIG. 3A. The vertical plane A-A′ is the cut plane of the vertical cross-sectional view of FIG. 3A.

FIG. 4 is a schematic vertical cross-sectional view of the exemplary structure after formation of support pillar structures according to an embodiment of the present disclosure.

FIGS. 5A-5F are sequential vertical cross-sectional views of a memory opening during formation of a memory opening fill structure according to an embodiments of the present disclosure.

FIG. 6A is a vertical cross-sectional view of the exemplary structure after formation of memory opening fill structures according to an embodiment of the present disclosure.

FIG. 6B is a top-down view of the exemplary structure of FIG. 6A. The vertical plane A-A′ is the cut plane of the vertical cross-sectional view of FIG. 6A.

FIG. 7A is a vertical cross-sectional view of the exemplary structure after formation of lateral isolation trenches according to an embodiment of the present disclosure.

FIG. 7B is a top-down view of the exemplary structure of FIG. 7A. The vertical plane A-A′ is the cut plane of the vertical cross-sectional view of FIG. 7A.

FIG. 8A is a vertical cross-sectional view of the exemplary structure after formation of a source-level cavity according to an embodiment of the present disclosure.

FIG. 8B is a magnified vertical cross-sectional view of a region of the exemplary structure of FIG. 8A around a memory opening fill structure.

FIG. 9A is a vertical cross-sectional view of the exemplary structure after formation of a source contact layer according to an embodiment of the present disclosure.

FIG. 9B is a magnified vertical cross-sectional view of a region of the exemplary structure of FIG. 9A around a memory opening fill structure.

FIG. 10 is a vertical cross-sectional view of the exemplary structure after formation of laterally-extending cavities according to an embodiment of the present disclosure.

FIGS. 11A-11D are sequential vertical cross-sectional views of a region of the exemplary structure during formation of an outer blocking dielectric layer and an electrically conductive layer in each of the laterally-extending cavities according to an embodiment of the present disclosure.

FIG. 12 is a vertical cross-sectional view of the exemplary structure after formation of electrically conductive layers according to an embodiment of the present disclosure.

FIG. 13A is a vertical cross-sectional view of the exemplary structure after formation of lateral isolation trench fill structures and contact via structures according to an embodiment of the present disclosure.

FIG. 13B is a top-down view of the exemplary structure of FIG. 13A. The vertical plane A-A′ is the cut plane of the vertical cross-sectional view of FIG. 13A.

FIG. 14A is a vertical cross-sectional view of the exemplary structure after formation of bit lines and bit-line-level metal lines according to an embodiment of the present disclosure.

FIG. 14B is a top-down view of the exemplary structure of FIG. 14A. The vertical plane A-A′ is the cut plane of the vertical cross-sectional view of FIG. 14A.

FIG. 15 is a vertical cross-sectional view of the exemplary structure after formation of a memory die according to an embodiment of the present disclosure.

FIG. 16 is a vertical cross-sectional view of a logic die according to an embodiment of the present disclosure.

FIG. 17 is a vertical cross-sectional view of the exemplary structure after formation of a bonded assembly of the memory die and the logic die according to an embodiment of the present disclosure.

FIG. 18 is a vertical cross-sectional view of the exemplary structure after removal of the substrate, the first stopper layer, and the second stopper layer from the memory die according to an embodiment of the present disclosure.

FIGS. 19A-19F are sequential vertical cross-sectional views of a region of the exemplary structure around a memory opening fill structure during modification of a bottom portion of the memory opening fill structure and formation of a backside electrode contact layer according to an embodiment of the present disclosure.

FIG. 20 is a vertical cross-sectional view of the exemplary structure after formation of the backside electrode contact layer.

### DETAILED DESCRIPTION

As discussed above, the embodiments of the present disclosure are directed to a three-dimensional memory device including memory opening fill structures each including a respective backside gate electrode and methods for manufacturing the same, the various aspects of which are described below. Embodiments of the disclosure can be employed to form various structures including a multilevel memory structure, non-limiting examples of which include semiconductor devices such as three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a surface of a structural element has a “convex profile” in a cross-sectional view if the surface is contoured such that a center of curvature of a curved segment of the surface is located on a side of the structural element relative to the surface of the structural element in the cross-sectional view. As used herein, a surface of a structural element has a “concave profile” in a cross-sectional view if the surface is contoured such that a center of curvature of a curved segment of the surface is located on an opposite side of the structural element relative to the surface of the structural element in the cross-sectional view. As used herein, a surface of a structural element is a “convex surface” if the surface has a convex profile in a cross-sectional view. A surface is a “vertically-convex surface” if the surface has a convex profile in a vertical cross-sectional view. A surface is a “vertically-concave surface” if the surface has a convex profile in a vertical cross-sectional view. A surface is a “vertically-straight surface” if the surface has no curvature in a vertical cross-sectional view. A surface is a “horizontally-convex surface” if the surface has a convex profile in a horizontal cross-sectional view. A surface is a “horizontally-concave surface” if the surface has a concave profile in a vertical cross-sectional view. A surface is a “horizontally-straight surface” if the surface has no curvature in a horizontal cross-sectional view. Generally, convexity or concavity in a vertical cross-sectional view is independent of convexity or concavity in a horizontal cross-sectional view.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may optionally include a curvature along a direction that is perpendicular to the vertical direction or the substantially vertical direction.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

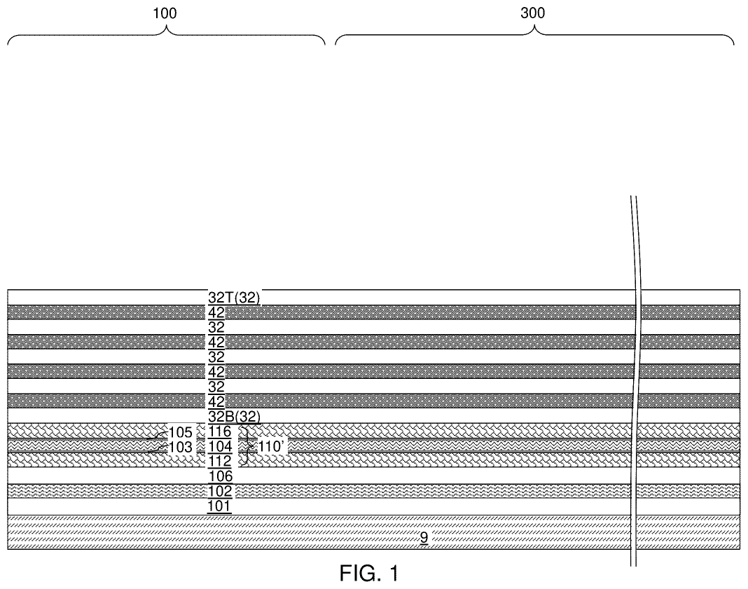

Referring to FIG. 1, an exemplary structure according to an embodiment of the present disclosure is illustrated. The exemplary structure comprises a substrate 9, which may be a carrier substrate that is subsequently removed. The substrate 9 may be a semiconductor substrate or a conductive substrate. For example, the substrate 9 may comprise a commercially available silicon wafer.

At least one stopper layer (101, 102) can be subsequently formed above the substrate 9. The at least one stopper layer (101, 102) comprise at least one material that may be subsequently employed to facilitate removal of the substrate 9 while minimizing removal of material portions to be subsequently formed above the at least one stopper layer (101, 102). In an illustrative example, the at least one stopper layer (101, 102) may comprise a first stopper layer 101 including a first stopper material that is different from the material of the substrate 9 and can function as a stopper material during subsequent removal of a topmost portion of the substrate 9. The first stopper layer 101 may function as an etch-stop material layer if an etch process is employed to remove the topmost portion of the substrate 9, or may function as a polish-stop layer if a polishing process, such as a chemical mechanical polishing process, is subsequently employed to remove the topmost portion of the substrate 9. In an illustrative example, if the substrate 9 comprises a semiconductor material such as silicon, the first stopper layer 101 may comprise silicon oxide. The second stopper layer 102 comprises a second stopper material that is different from the first stopper material and can function as a stopper material during subsequent removal of the first stopper layer 101. For example, if the first stopper layer 101 comprises silicon oxide, the second stopper layer 102 may comprise a semiconductor material, such as polysilicon. The thicknesses of the first stopper layer 101 and the second stopper layer 102 may be selected such that the first stopper layer 101 and the second stopper layer 102 may properly function as stopper structures. In an illustrative example, the first stopper layer 101 may comprise silicon oxide and may have a thickness in a range from 100 nm to 1,000 nm, and the second stopper layer 102 may comprise polysilicon and may have a thickness in a range from 50 nm to 300 nm.

A backside insulating layer 106 can be formed over the second stopper layer 102. The backside insulating layer 106 comprises an insulating material, such as a silicate glass (i.e., silicon oxide) material. The thickness of the backside insulating layer 106 may be in a range from 50 nm to 600 nm, such as from 100 nm to 300 nm, although lesser and greater thicknesses may also be employed.

In-process source-level material layers 110′ can be formed over the backside insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

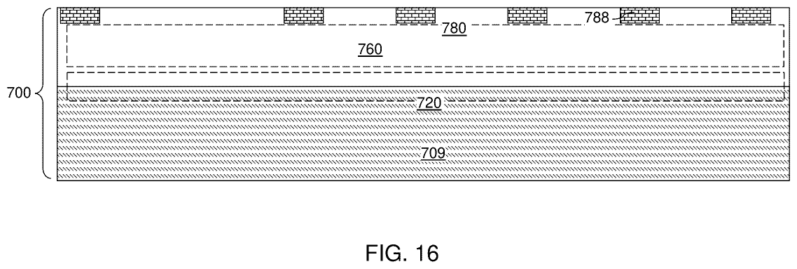

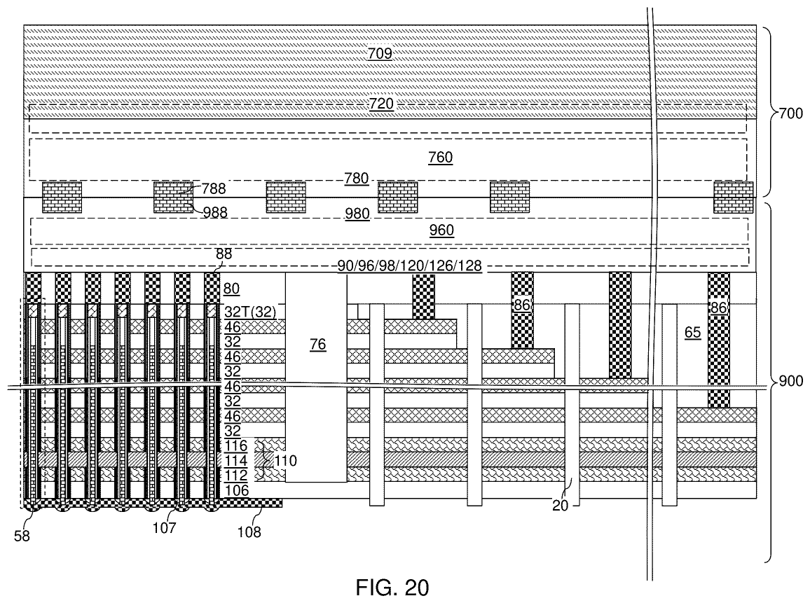

An alternating stack of first material layers and second material layers can be formed over the in-process source-level material layers 110′. In an alternative embodiment, the in-process source-level material layers 110′ and the backside insulating layer 106 may be omitted, and the alternating stack is formed directly on a surface of the substrate 9. In another alternative embodiment described below with respect to FIG. 20, a peripheral circuit is formed on the same substrate as the alternating stack. For example, the peripheral circuit may comprise word line driver regions, bit line driver regions, sense amplifier regions, input/output buffer regions, etc. In this alternative embodiment, a separate logic die containing the peripheral circuit described below with respect to FIG. 16 may be omitted. In this alternative embodiment, the alternating stack may be deposited on the in-process source-level material layers 110′ or the in-process source-level material layers 110′ may be omitted, and the alternating stack may be deposited on the backside insulating layer 106.

In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed.

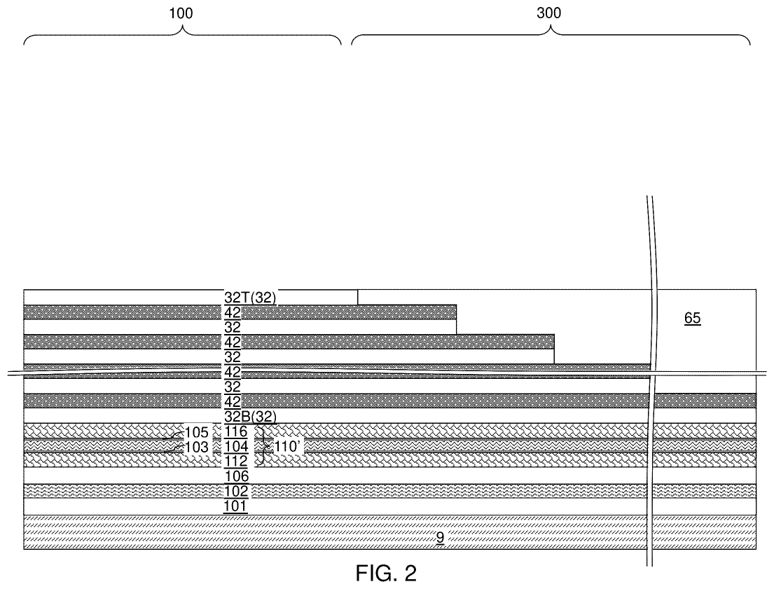

Referring to FIG. 2, stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may optionally be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

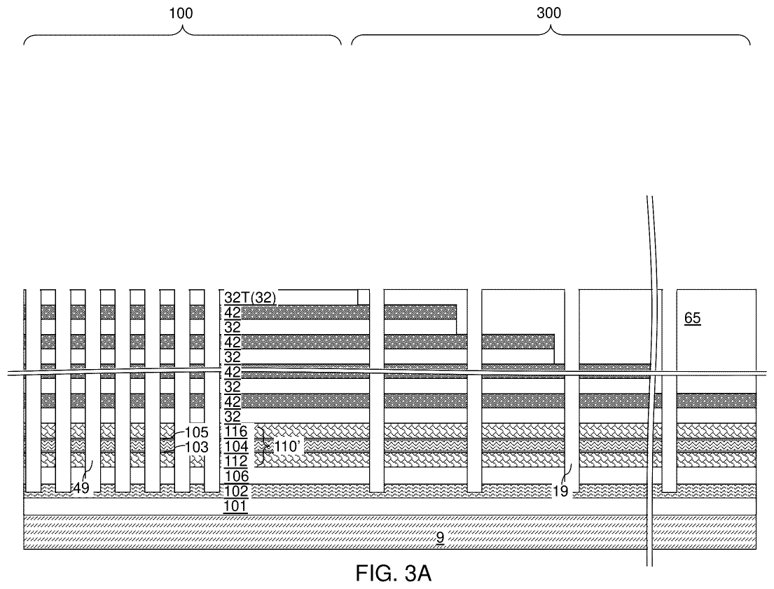

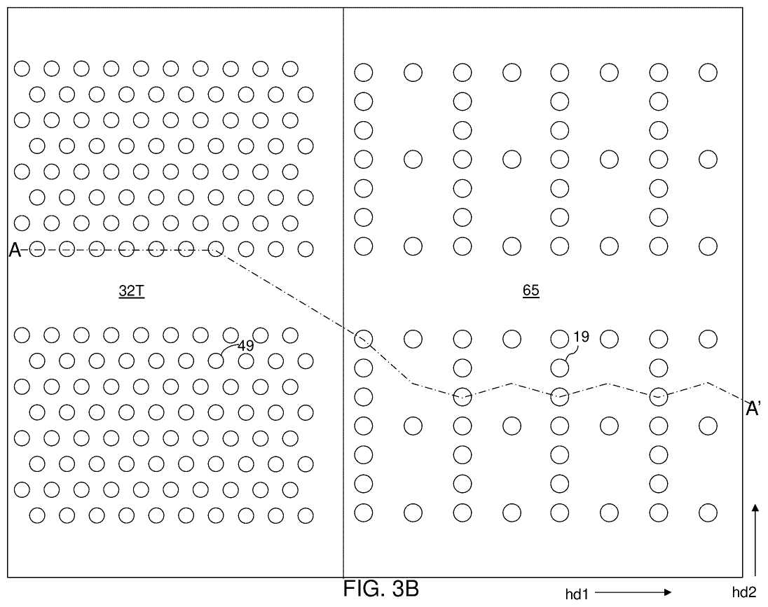

Referring to FIGS. 3A-3C, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can vertically extend through the alternating stack (32, 42) and at least partially into the in-process source-level material layers 110′. In one embodiment illustrated in FIG. 3A, bottom surfaces of the memory openings 49 and the support openings 19 may be formed within the second stopper layer 102. In this embodiment, the memory openings 49 and the support openings 19 extend through the in-process source-level material layers 110′ and the backside insulating layer 106 and partially into the second stopper layer 102. In an alternative embodiment, the bottom surfaces of the memory openings 49 and the support openings 19 may be formed within the lower source-level semiconductor layer 112 or at an interface between the lower source-level semiconductor layer 112 and the backside insulating layer 106.

The support openings 19 may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 300 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd1. Multiple clusters of memory openings 49, each containing a respective two-dimensional periodic array of memory openings 49, may be formed in the memory array region 100. The clusters of memory openings 49 may be laterally spaced apart along the second horizontal direction hd2.

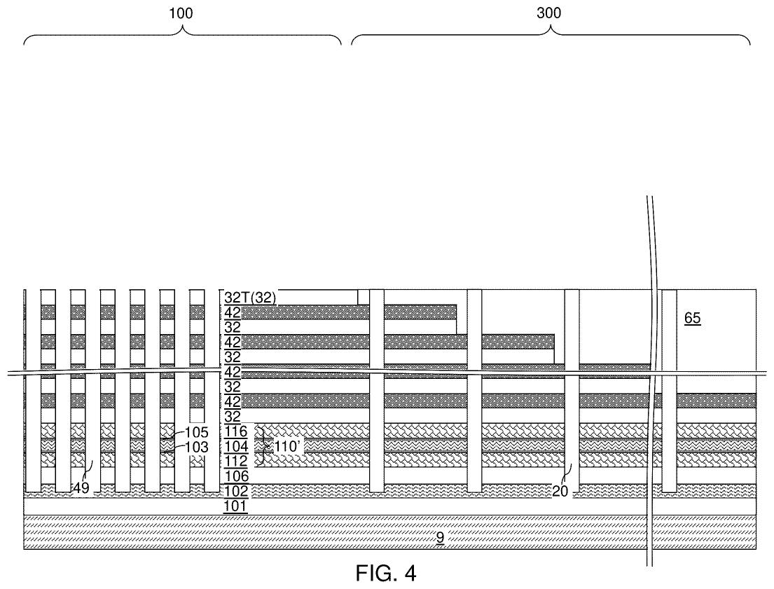

Referring to FIG. 4, an optional etch stop liner (not shown) and a sacrificial fill material (not shown) can be deposited in the memory openings 49 and the support openings. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 and the support openings 19 constitute sacrificial memory opening fill structures (not shown) and sacrificial support opening fill structures (not shown).

A photoresist layer (not shown) can be applied over the alternating stack (32, 42) and the retro-stepped dielectric material portion 65, and can be lithographically patterned to cover the memory array region 100 without covering the contact region 300. The sacrificial support opening fill structures and portions of the optional etch stop liner in the contact region 300 can be removed selective to the materials of the retro-stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

A dielectric fill material such as silicon oxide can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers.

Subsequently, the sacrificial memory opening fill structures and portions of the optional etch stop liner in the memory array region 100 can be removed selective to the materials of the retro-stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

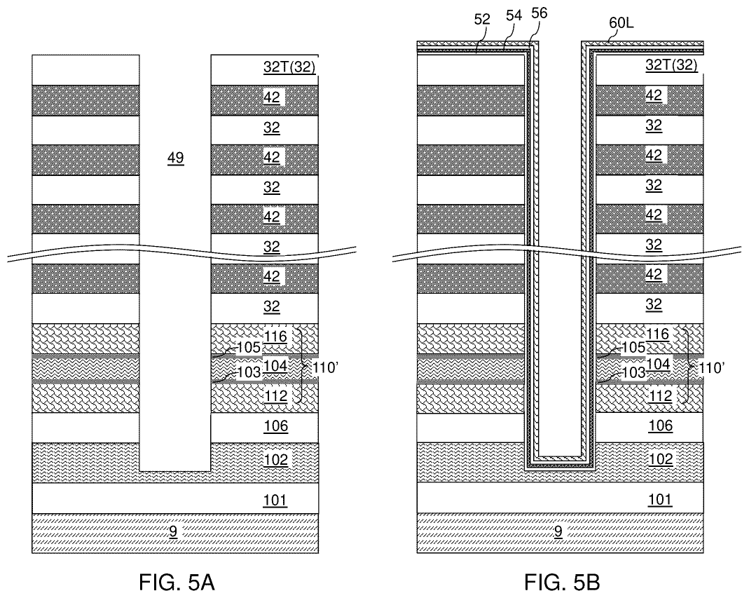

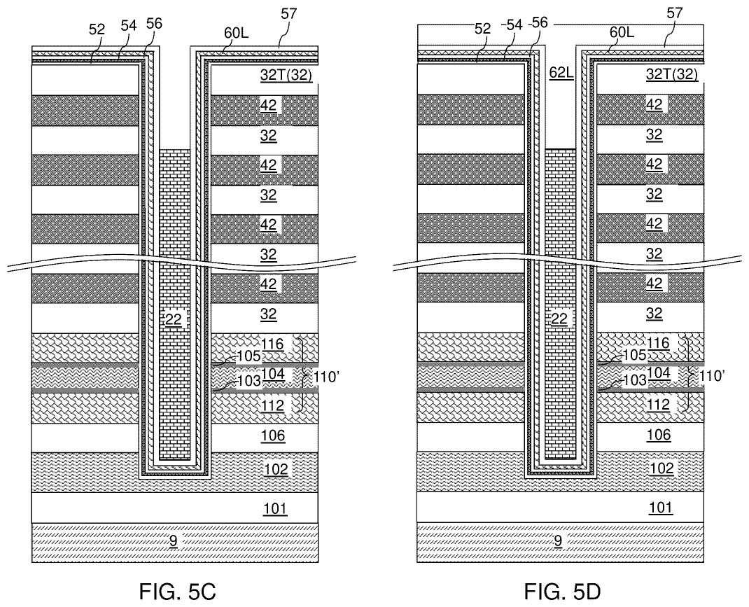

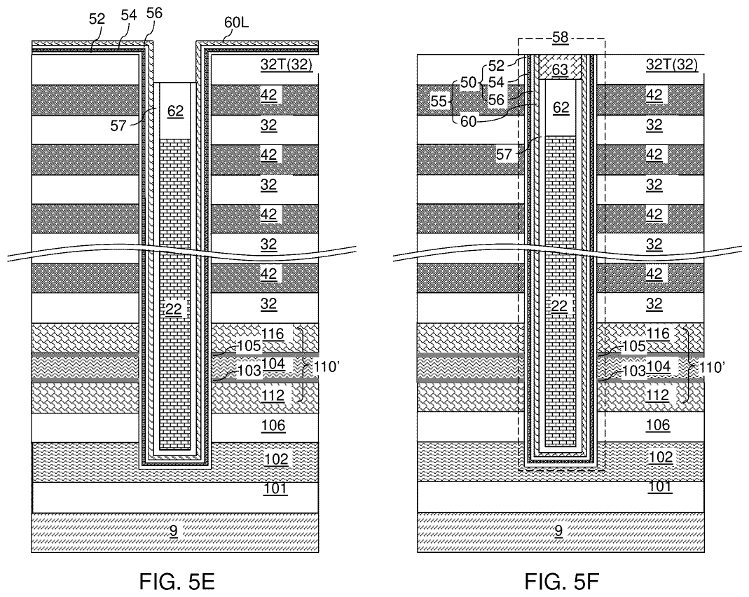

FIGS. 5A-5F are sequential vertical cross-sectional views of a memory opening 49 during formation of a memory opening fill structure 58 according to an embodiments of the present disclosure. The combination of a memory opening fill structure 58 and proximal portions of electrically conductive layers to subsequently replace the sacrificial material layers 42 can form a NAND string including a backside gate electrode 22 according to an embodiment of the present disclosure.

Referring to FIG. 5A, a memory opening 49 is illustrated after the processing steps of FIG. 4.

Referring to FIG. 5B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. The thickness of the semiconductor channel material layer 60L may be in a range from 5 nm to 50 nm, although lesser and greater thicknesses may also be employed. In one embodiment, the semiconductor channel material layer 60L may be deposited as a conformal semiconductor material layer (e.g., amorphous silicon or small grain size polysilicon) having a greater thickness, and an anneal process can be performed to crystallize the material of the conformal semiconductor material layer to form a polycrystalline semiconductor material (e.g., polysilicon) with a relatively large grain size. Subsequently, the polycrystalline material of the conformal semiconductor material layer may be thinned to a target thickness to form the semiconductor channel material layer 60L.

Referring to FIG. 5C, a backside gate dielectric layer 57 can be conformally deposited on the physically exposed surface of the semiconductor channel material layer 60L. The backside gate dielectric layer 57 may comprise any suitable gate dielectric material. For example, the backside gate dielectric layer 57 may comprise silicon oxide and/or at least one dielectric metal oxide (such as aluminum oxide and/or at least one transition metal oxide). The thickness of the backside gate dielectric layer 57 may be in a range from 5 nm to 30 nm, although lesser and greater thicknesses may also be employed.

An electrically conductive material can be deposited to fill the remaining respective voids in the memory openings 49. The electrically conductive material may comprise a heavily doped semiconductor material (such as heavily doped polysilicon) and/or at least one metallic material (such as TiN, TaN, WN, MON, Ti, Ta, W, Mo, etc.). The electrically conductive material can be deposited such that the voids in the memory openings 49 are filled with the conductive material, and a horizontally-extending portion of the electrically conductive material overlies the horizontally-extending portions of the backside gate dielectric layer 57 that overlies the alternating stack (32, 42). A selective recess etch process that recesses the electrically conductive material with high selectivity to the material of the backside gate dielectric layer 57 can be performed to vertically recess the electrically conductive material. The top surface of each remaining portion of the electrically conductive material can be formed below the horizontal plane including the bottom surface of the topmost sacrificial material layer 42. Each remaining portion of the electrically conductive material comprises a backside gate electrode 22.

Referring to FIG. 5D, a dielectric core layer 62L comprising a dielectric fill material can be deposited in each recess that overlies the top surfaces of the backside gate electrodes 22. The dielectric core layer 62L may comprise a silicate glass material.

Referring to FIG. 5E, the dielectric core layer 62L and the backside gate dielectric layer 57 can be vertically recessed such that each remaining portion of the dielectric core layer 62L and the backside gate dielectric layer 57 has a top surface at or adjacent to the horizontal plane including the bottom surface of the topmost insulating layers 32T. Each remaining portion of the dielectric core layer 62L constitutes a dielectric core 62. The backside gate dielectric layer 57 and the dielectric core layer 62L may comprise the same material (e.g., silicon oxide) and can be recessed together during the same recess etch.

Referring to FIG. 5F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited material layers can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

In summary, a memory opening fill structure 58 can be formed in each memory opening 49. Each memory opening fill structure 58 comprises, from outside to inside and in an order of formation, a memory film 50, a vertical semiconductor channel 60, a backside gate dielectric layer 57, and a backside gate electrode 22. The memory film 50 laterally surrounds the vertical semiconductor channel 60. In one embodiment, the memory film 50 comprises a layer stack including, from outside to inside, an optional blocking dielectric layer 52, the memory material layer 54, and dielectric liner 56. In one embodiment, the dielectric liner comprises a tunneling dielectric layer and the memory material layer 54 comprises a charge storage layer. The memory film 50 comprises a vertical stack of memory elements. In one embodiment, the vertical stack of memory elements comprises portions of the memory material layer 54 that are located at levels of the sacrificial material layers 42.

According to an aspect of the present disclosure, the memory opening fill structure 58 comprises a dielectric core 62 located over the top surface of the backside gate electrode 22. The dielectric core 62 can be laterally surrounded by the backside gate dielectric layer 57 and can contact a top surface of the backside gate electrode 22. In one embodiment, the backside gate electrode 22 vertically extends through a predominant subset of the sacrificial material layers 42 that excludes at least the topmost sacrificial material layer 42 of the sacrificial material layers 42. This predominant subset of the sacrificial material layers will be subsequently replaced with word lines and source side select gate electrodes. The dielectric core 62 vertically extends through at least one sacrificial material layer 42 that includes the topmost sacrificial material layer 42. The total number of sacrificial material layer(s) 42 that the dielectric core 62 vertically extends through may be in a range from 1 to 10, such as from 2 to 4. These sacrificial material layers will be subsequently replaced with drain side select gate electrodes. A drain region 63 can be formed above the dielectric core 62 and the backside gate dielectric layer 57 and in contact with an end portion of the vertical semiconductor channel 60. The drain region 63 is electrically isolated from the backside gate electrode 22 by the dielectric core 62.

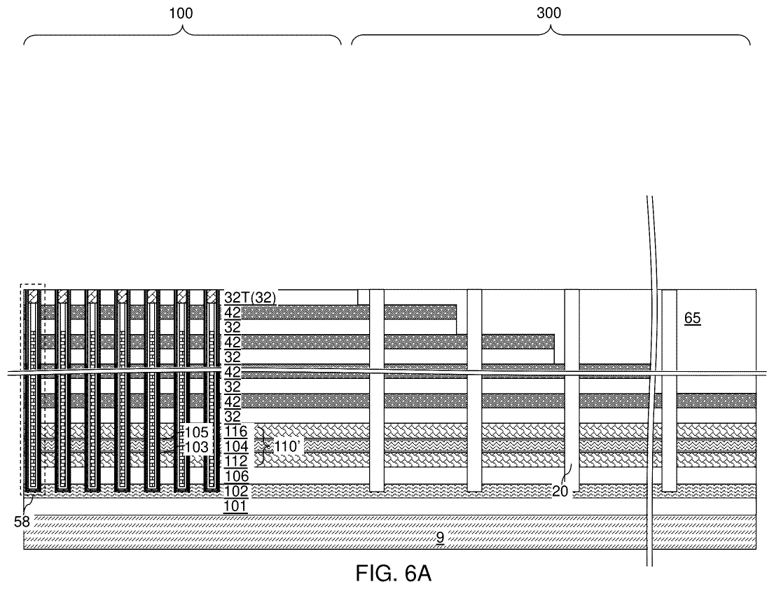

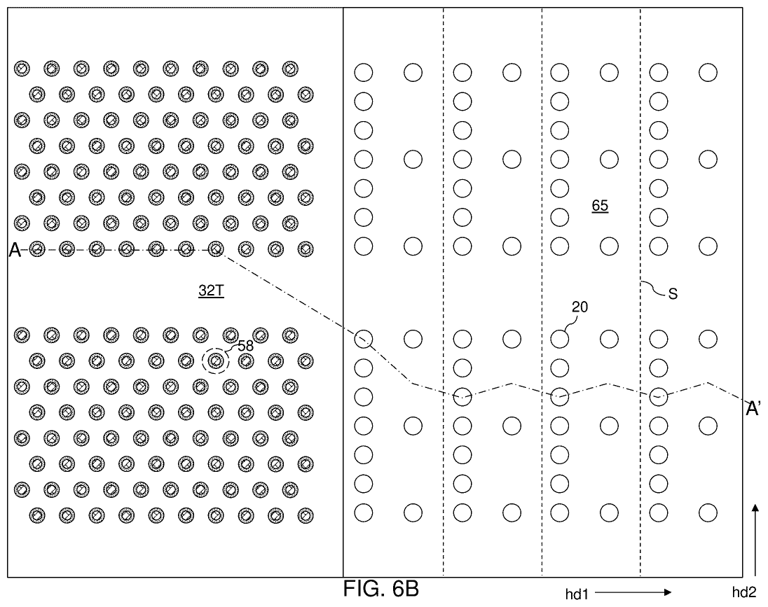

Referring to FIGS. 6A and 6B, the exemplary structure is illustrated after formation of memory opening fill structures 58 within the memory openings 49. Each of the memory opening fill structures 58 may comprise a memory film 50 and a vertical semiconductor channel 60. In summary, a combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

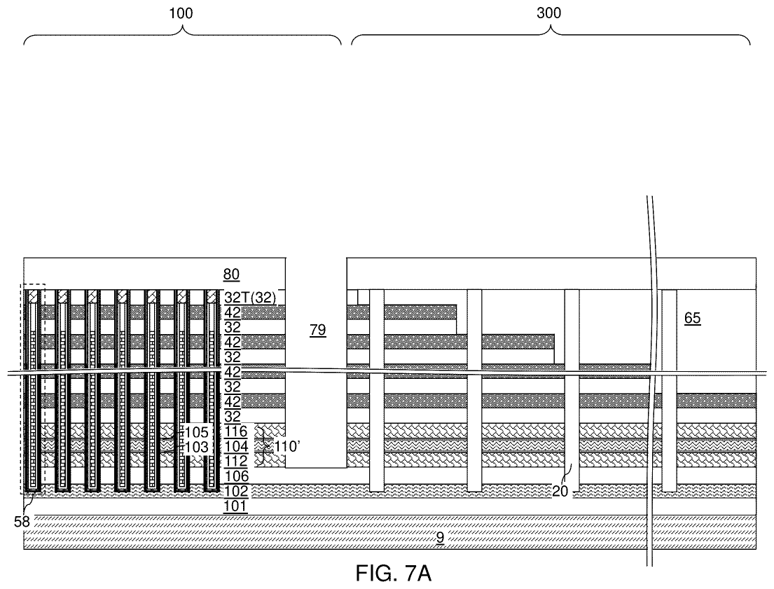

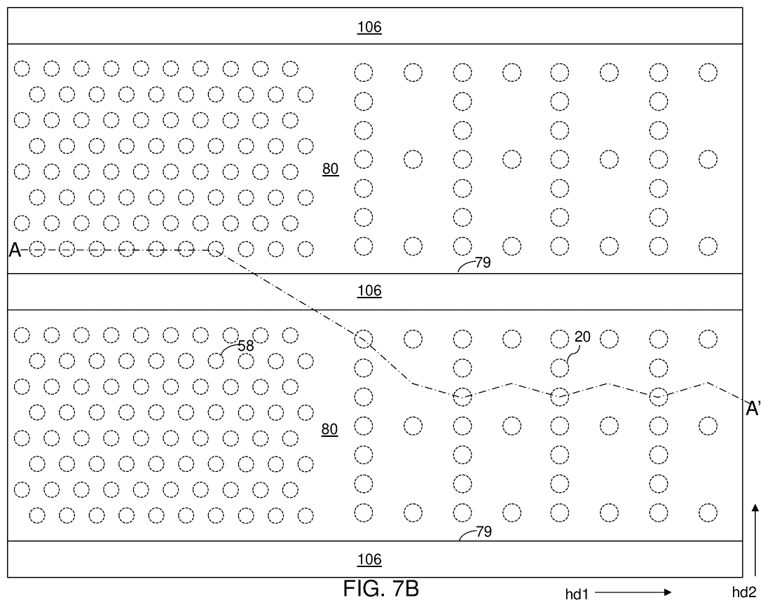

Referring to FIGS. 7A and 7B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the retro-stepped dielectric material portion 65, and at least a portion of the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and at least the upper portion of the in-process source-level material layers 110′, including the source-level sacrificial layer 104. In one embodiment, the lateral isolation trenches 79 extend through the entirely of the in-process source-level material layers 110′ and into an upper part of the backside insulating layer 106. However, the lateral isolation trenches 79 do not extend all the way through the backside insulating layer 106 to the second stopper layer 102 to avoid subsequently replacing the second stopper layer 102 with a conductive layer. Each of the lateral isolation trenches 79 may comprise a respective pair of lengthwise sidewalls that are parallel to the first horizontal direction hd1 and vertically extend from the backside insulating layer 106 to the top surface of the contact-level dielectric layer 80. A top surface of the backside insulating layer 106 can be physically exposed underneath each lateral isolation trench 79. The lateral isolation trenches 79 isolate adjacent memory blocks from each other along the second horizontal direction hd2. The photoresist layer can be subsequently removed, for example, by ashing.

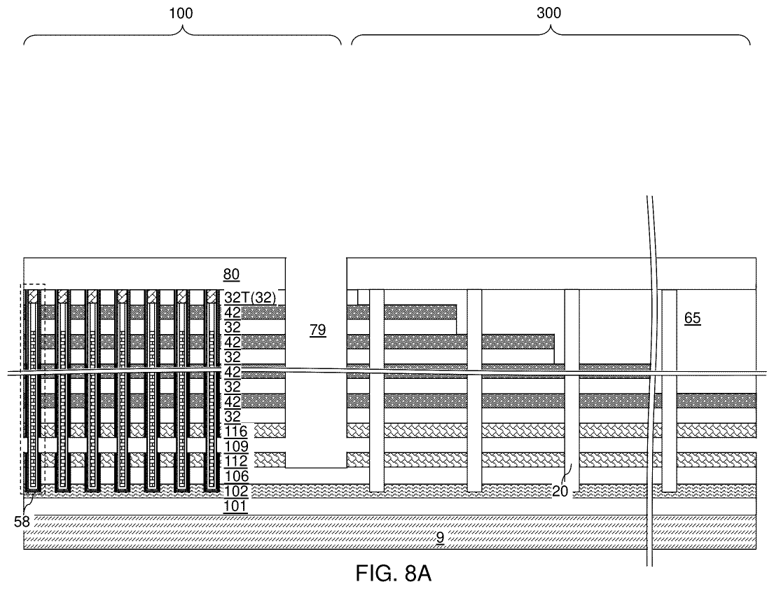

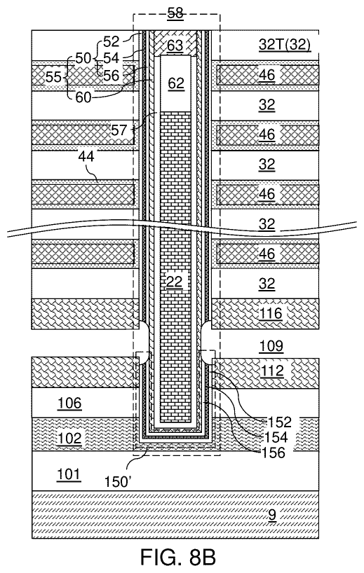

Referring to FIGS. 8A and 8B, an etchant that etches the material of the source-level sacrificial layer 104 selective to the materials of the alternating stack (32, 42), the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the collateral structural changes to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners.

Each memory film 50 is divided into a primary remaining portion that overlies the source cavity 109, and a bottom tip portion that underlies the source cavity 109. The primary remaining portion of each memory film 50 is hereafter referred to as a memory film 50. The bottom tip portion of each memory film 50 is herein referred to as a dielectric layer stack 150′. Each dielectric layer stack 150′ has a same set of materials as the memory films 50. For example, each dielectric layer stack 150′ may comprise, from outside to inside, an outer dielectric layer 152 having the same material composition and the same thickness as a blocking dielectric layer 52, an intermediate dielectric layer 154 having the same material composition and the same thickness as a memory material layer 54, and an inner dielectric layer 156 having the same material composition and the same thickness as a dielectric liner 56 (which may be a tunneling dielectric layer).

A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

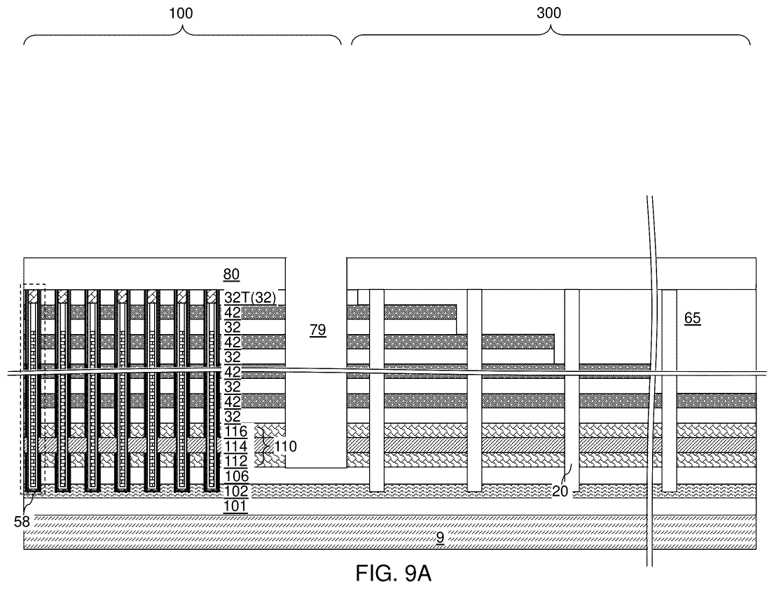

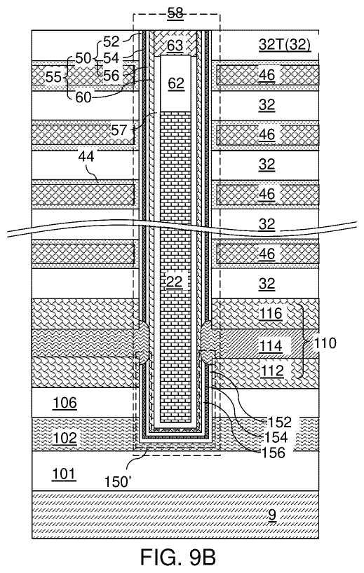

Referring to FIGS. 9A and 9B, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

Thus, the source-level sacrificial layer 104 can be replaced with a source contact layer 114 such that the source contact layer 114 contacts an outer sidewall of each vertical semiconductor channel 60 within the memory opening fill structures 58. In one embodiment, the source layer 110 comprises a source contact layer 114 in contact with a cylindrical surface segment of the outer sidewall of each vertical semiconductor channel 60; an upper source-level semiconductor layer 116 contacting a top surface of the source contact layer 114 and contacting a cylindrical surface segment of each memory film 50; and a lower source-level semiconductor layer 112 contacting a bottom surface of the source contact layer 114 and contacting a cylindrical surface segment of each dielectric layer stack 150′.

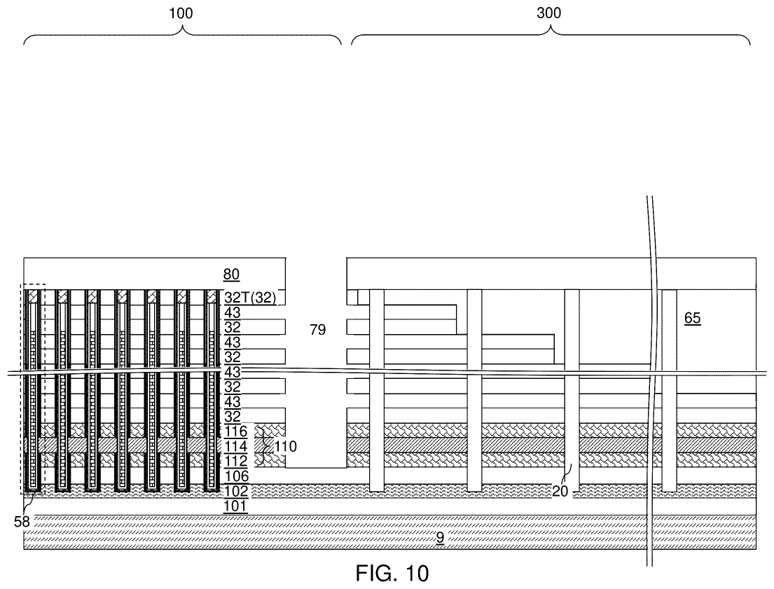

Referring to FIG. 10, an isotropic etch process can be performed to remove the sacrificial material layers 42 selective to the insulating layers 32, the backside insulating layer 106, the memory opening fill structures 58, the sacrificial etch stop liners 71, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary structure is immersed in phosphoric acid at or near the boiling point of the phosphoric acid. A suitable clean process may be performed as needed. In summary, the laterally-extending cavities 43 can be formed by removing the sacrificial material layers 42 selective to the insulating layers 32 and the memory opening fill structures 58.

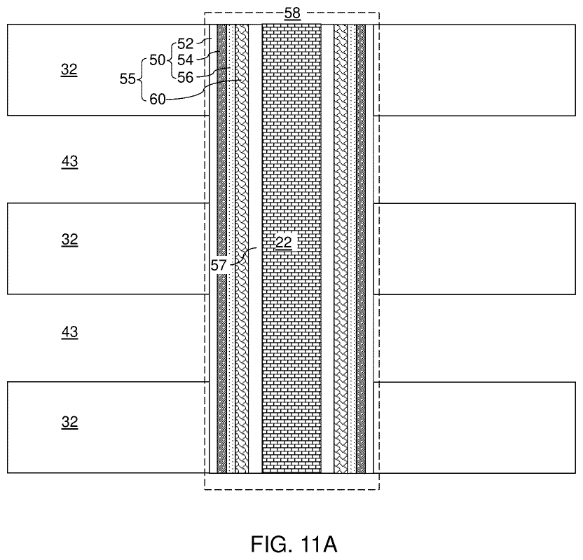

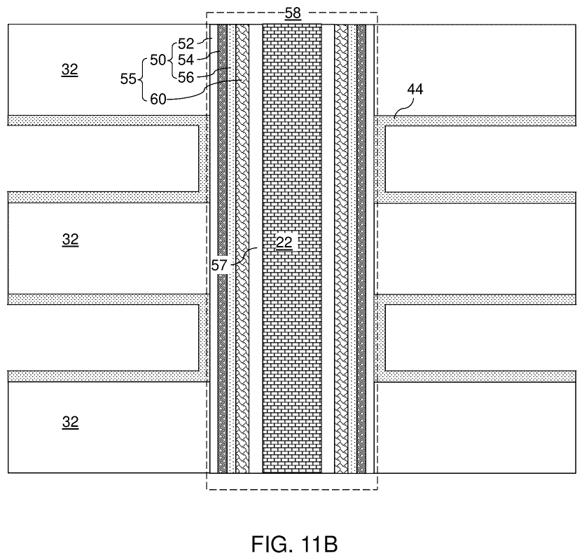

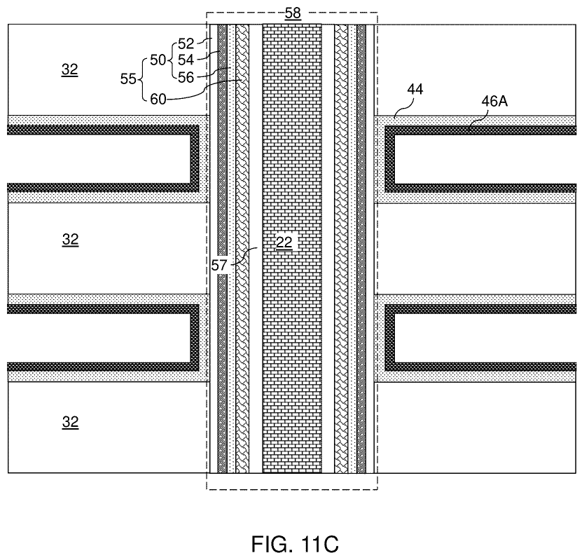

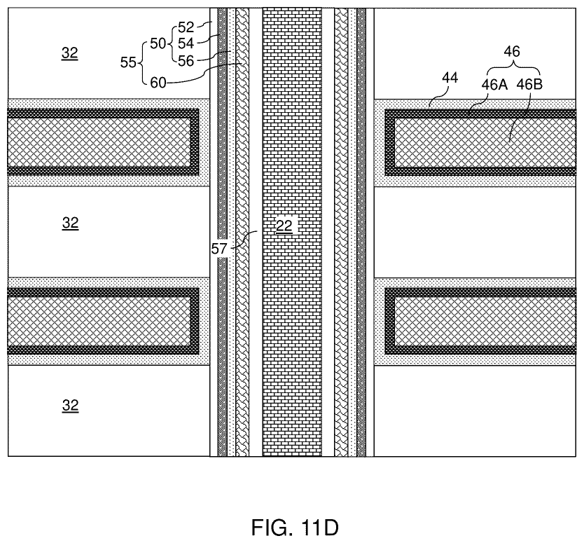

FIGS. 11A-11D are sequential vertical cross-sectional views of a region of the exemplary structure during formation of an optional outer blocking dielectric layer 44 and an electrically conductive layer 46 in each of the laterally-extending cavities 43 according to an embodiment of the present disclosure.

Referring to FIG. 11A, a region of the exemplary structure is illustrated after the processing steps of FIG. 10. Cylindrical outer surface segments of each memory opening fill structure 58 and horizontally-extending surfaces of the insulating layers 32 can be exposed to the laterally-extending cavities 43.

Referring to FIG. 11B, an outer blocking dielectric layer 44 may be optionally deposited directly on the physically exposed cylindrical outer surface segments of each memory opening fill structure 58 and the physically exposed surfaces of the insulating layers 32 by a conformal deposition process. The outer blocking dielectric layer 44 may comprise a dielectric metal oxide material, such as aluminum oxide or a dielectric oxide of a transition metal. For example, an atomic layer deposition (ALD) process or a chemical vapor deposition (CVD) process may be employed to deposit the outer blocking dielectric layer 44. The outer blocking dielectric layer 44 may have a thickness in a range from 1 nm to 5 nm, although lesser and greater thicknesses may also be employed. In one embodiment, the outer blocking dielectric layer 44 contacts an entirety of physically exposed surfaces of the insulating layers 32, and physically exposed sidewall segments of the memory opening fill structures 58.

Referring to FIG. 11C, a metallic barrier liner 46A can be conformally deposited on the physically exposed surfaces of the outer blocking dielectric layer 44. The metallic barrier liner 46A comprises a metallic barrier material such as TiN, TaN, WN, or MoN. The metallic barrier liner 46A may be deposited by a conformal deposition process such as an atomic layer deposition process or a chemical vapor deposition process. The thickness of the metallic barrier liner 46A may be in a range from 1 nm to 8 nm, such as from 2 nm to 5 nm, although lesser and greater thicknesses may also be employed.

Referring to FIG. 11D, a metal layer 46B including a metal at an atomic percentage greater than 95%, and/or greater than 99%, and/or greater than 99.8%, may be deposited in remaining volumes of the laterally-extending cavities 43. In one embodiment, the metal may comprise tungsten, molybdenum, ruthenium or cobalt. The metal layer 46B may be deposited by a conformal deposition process such as a chemical vapor deposition process, and can fill remaining volumes of the laterally-extending cavities 43. In one embodiment, the metal layer 46B comprises tungsten deposited on the metallic barrier liner 46A by a two-step process including forming a silicon or boron containing nucleation layer using a first B₂H₆ or silane (SiH₄) gas pre-treatment step followed by depositing a tungsten layer using tungsten hexafluoride or another suitable tungsten precursor in a second step. The tungsten precursor gas may optional also be provided during the first step.

An anisotropic etch process can be performed to remove portions of the metal layer 46B and the metallic barrier liner 46A and optionally the outer blocking dielectric layer 44 from inside the volumes of the lateral isolation trenches 79 and from above the contact-level dielectric layer 80. Each contiguous remaining portion of the combination of the metal layer 46B and the metallic barrier liner 46A located within a volume of a respective laterally-extending cavity 43 constitutes an electrically conductive layer 46. Each electrically conductive layer 46 can be laterally spaced from the memory opening fill structures 58, a respective overlying one of the insulating layers 32, and a respective underlying one of the insulating layers 32 by the outer blocking dielectric layer 44. Alternating stacks (32, 46) of insulating layers 32 and electrically conductive layers 46 is thus formed. The alternating stacks (32, 46) of insulating layers 32 and electrically conductive layers 46 can be laterally spaced apart from each other along the second horizontal direction hd2 by the lateral isolation trenches 79.

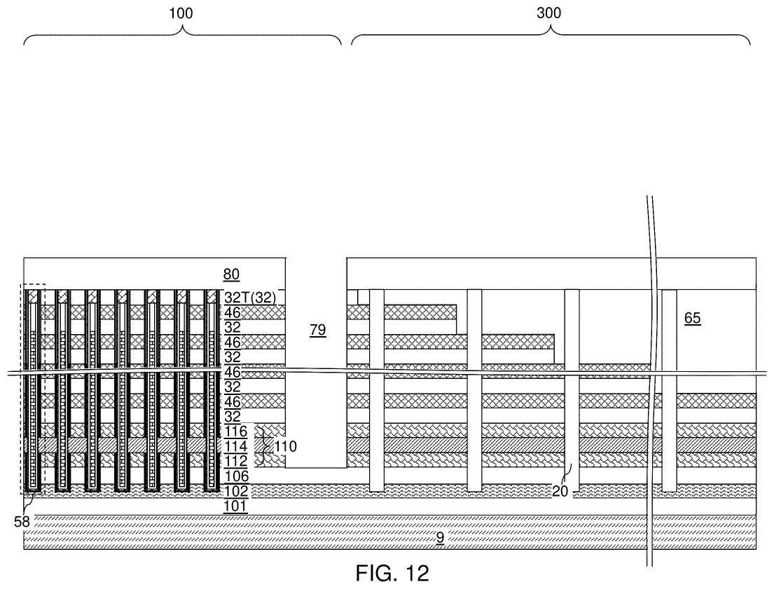

Referring to FIG. 12, the exemplary structure is illustrated after the processing steps of FIG. 11D. While the optional outer blocking dielectric layer 44 is not expressly illustrated in FIG. 12 for the purpose clarity, it is understood that the optional outer blocking dielectric layer 44 may be present in the exemplary structure, as illustrated in FIG. 11D.

Within each memory opening fill structure 58, a dielectric core 62 is laterally surrounded by the backside gate dielectric layer 57 and contacts a top surface of a backside gate electrode 22. In one embodiment, the backside gate electrode 22 vertically extends through a predominant subset of the electrically conductive layers 46 (e.g., word lines and source side select gate electrodes) that excludes at least a topmost electrically conductive layer 46 (e.g., one or more drain side select gate electrodes), and the dielectric core 62 vertically extends at least through the topmost electrically conductive layer 46. The total number of electrically conductive layers 46 (e.g., drain side select gate electrodes) that a dielectric core 62 vertically extends through may be in a range from 1 to 10, although a greater number may also be employed.

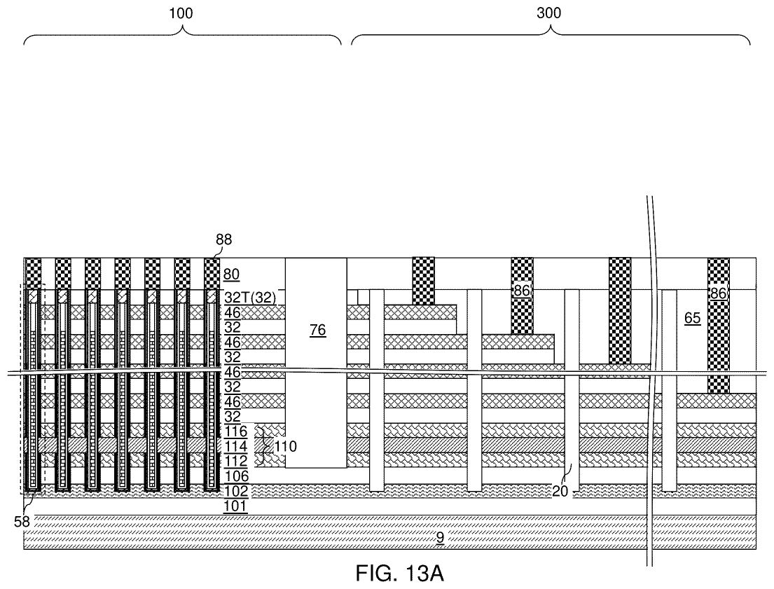

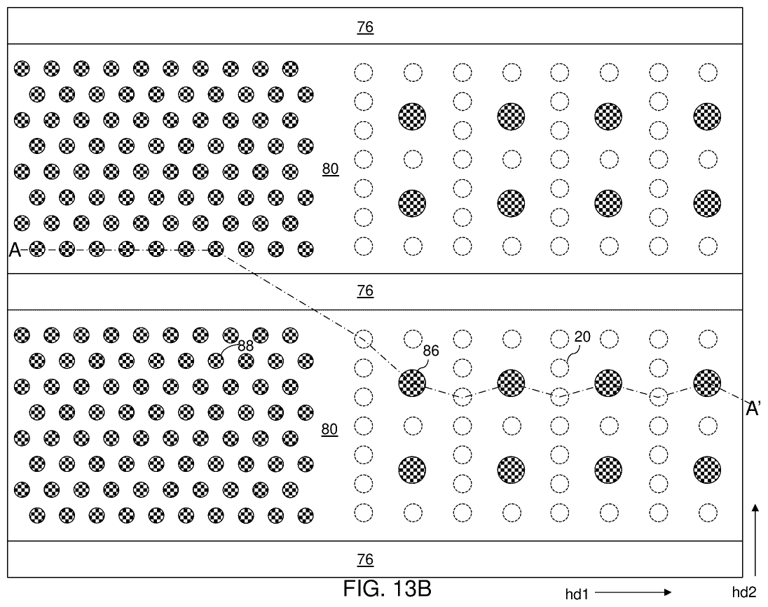

Referring to FIGS. 13A and 13B, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an isolation trench fill structure 76. Alternatively, each isolation trench fill structure 76 may comprise a combination of a tubular insulating spacer (not expressly shown) and a conductive connection via structure (not expressly shown) that is laterally surrounded by the tubular insulating spacer. In summary, an isolation trench fill structure 76 having an insulating sidewall vertically extends from a bottommost surface of an alternating stack (32, 46) to a topmost surface of the alternating stack (32, 46).

A photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via structures can be formed through the contact-level dielectric layer 80 and the retro-stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

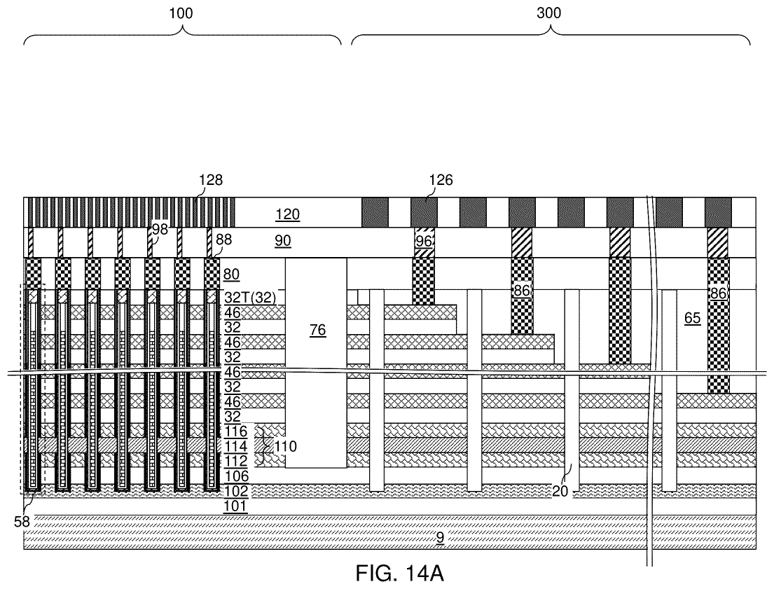

Referring to FIGS. 14A and 14B, a connection-level dielectric layer 90 can be formed above the contact-level dielectric layer 80. Connection via cavities can be formed through the connection-level dielectric layer 90, and can be filled with at least one conductive material (which may comprise at least one metallic material) to form connection-level via structures (98, 96). The connection-level via structures (98, 96) comprise drain connection via structures 98 that contact a respective one of the drain contact via structures 88, and layer connection via structures 96 that contact a respective one of the layer contact via structures 86.

A bit-line-level dielectric layer 120 can be formed above the connection-level dielectric layer 90. Bit-line-level line cavities can be formed through the bit-line-level dielectric layer 120, and can be filled with at least one conductive material (which may comprise at least one metallic material) to form bit-line-level metal lines (128, 126). The bit-line-level metal lines may comprise bit lines 128 that laterally extend along the second horizontal direction hd2, and bit-line-level interconnect metal lines 126 (not individually shown) that can be employed to provide electrical connection to the layer connection via structures 96.

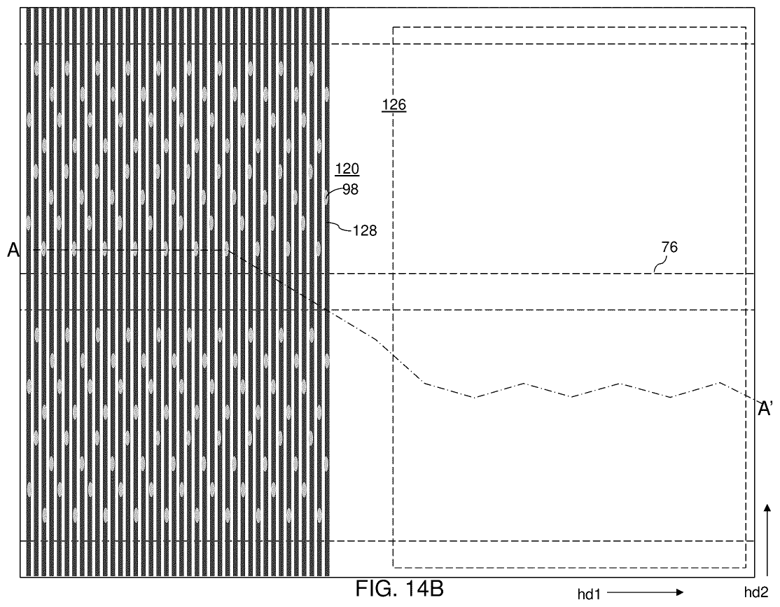

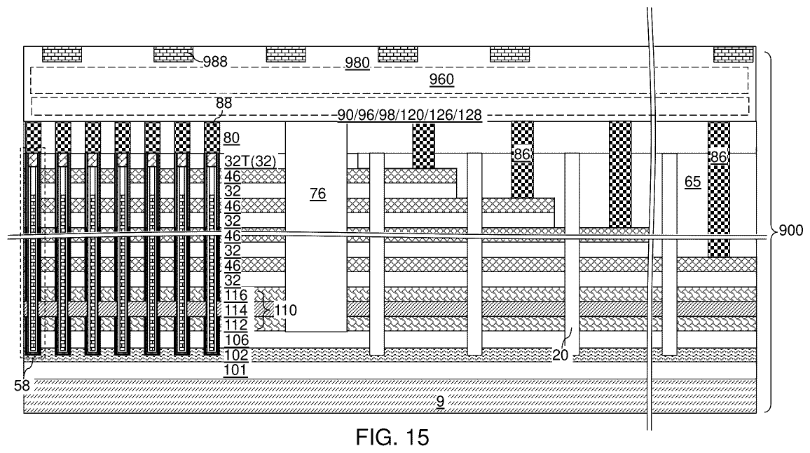

Referring to FIG. 15, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding the bit lines 128, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines for the three-dimensional memory array.

In summary, a memory die 900 comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers 32 and electrically conductive layers 46, and further comprises a two-dimensional array of NAND strings (e.g., the memory opening fill structures 58) vertically extending through the alternating stack (32, 46). In one embodiment, the electrically conductive layers 46 comprise word lines of the two-dimensional array of NAND strings. In one embodiment, the memory-side metal interconnect structures 980 comprise the bit lines 128 for the two-dimensional array of NAND strings.

Referring to FIG. 16, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

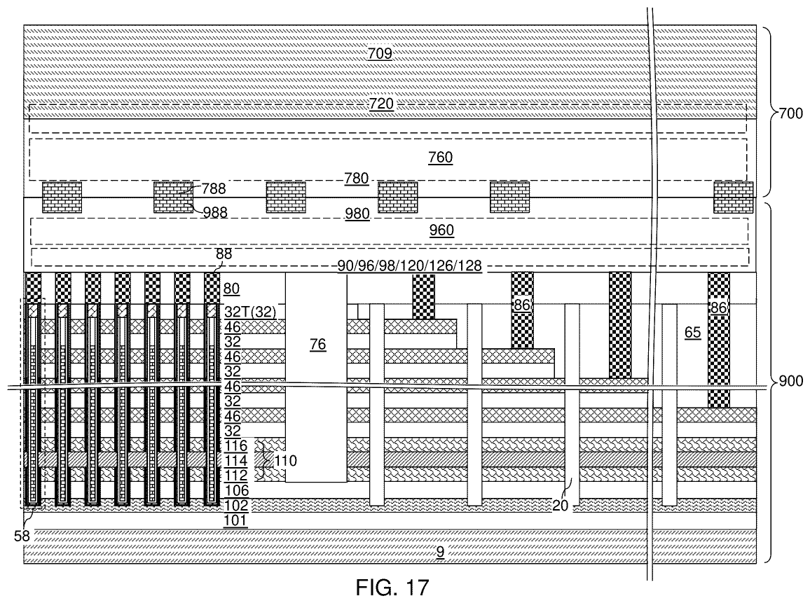

Referring to FIG. 17, a bonded assembly can be formed by bonding a logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

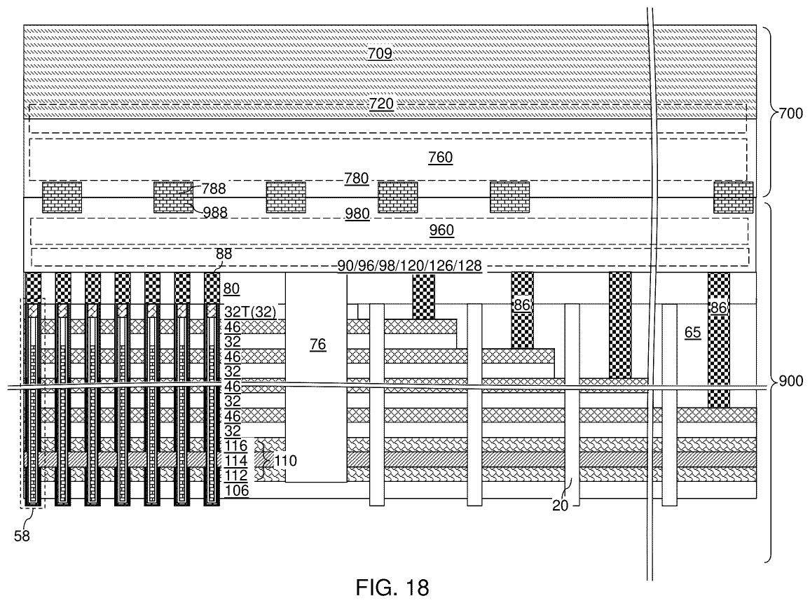

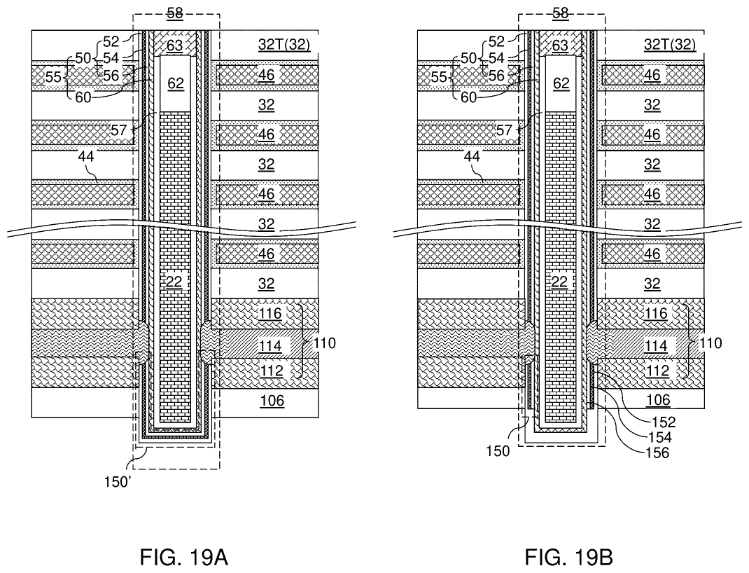

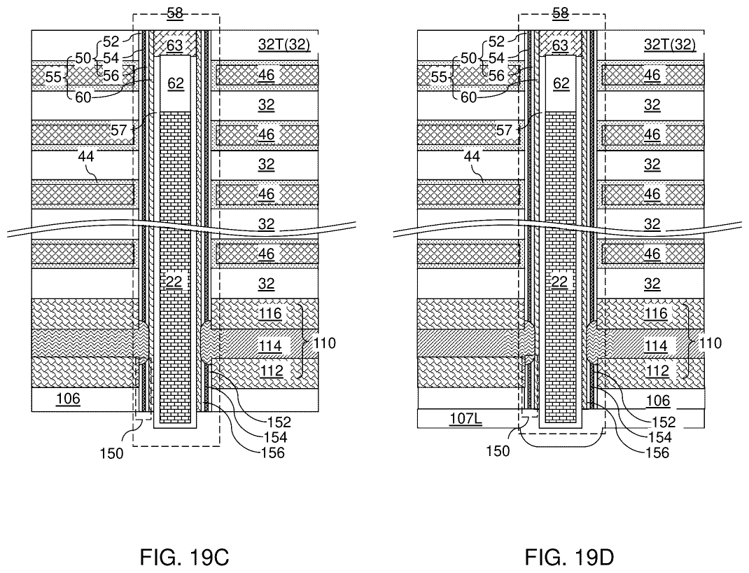

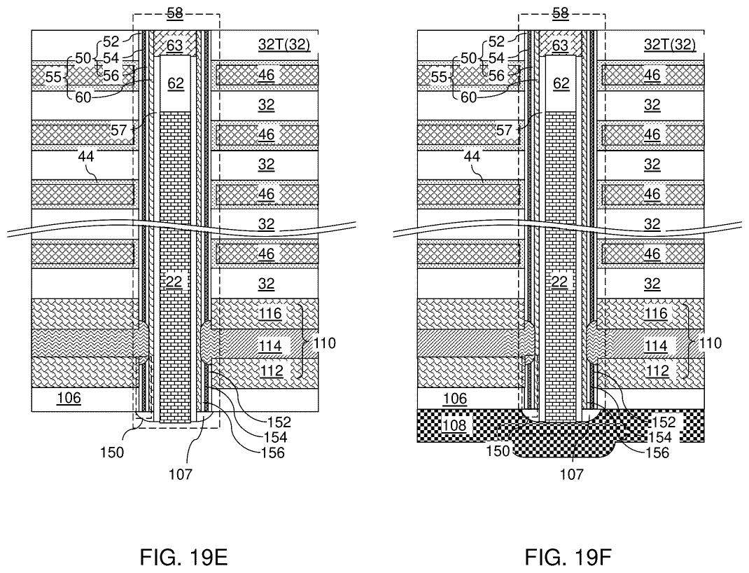

Referring to FIGS. 18 and 19A, the substrate 9 can be removed, for example, by grinding, polishing, cleaving, an isotropic etch process, and/or an anisotropic etch process. The bottom portion of the substrate 9 can be removed employing a removal process that provides a high material removal rate, and a top portion of the substrate 9 can be removed by performing a selective material removal process that removes the material of the substrate 9 selective to the material of the first stopper layer 101. In an illustrative example, the substrate 9 may comprise silicon and the first stopper layer 101 may comprise silicon oxide. In this case, the bottom portion of the substrate 9 can be removed by performing a grinding process, and the top portion of the substrate 9 may be removed by performing a wet etch process utilizing potassium hydroxide, which etches silicon selective to silicon oxide. Subsequently, a selective etch process may be performed to remove the first stopper layer 101 selective to the second stopper layer 102. For example, the second stopper layer 102 may comprise a semiconductor material, such as polysilicon, and the selective etch process may comprise a wet etch process employing dilute hydrofluoric acid. Thereafter, the second stopper layer 102 may be removed selective to the backside insulating layer 106. For example, a wet etch process using hot trimethyl-2 hydroxyethyl ammonium hydroxide (“hot TMY”) or tetramethyl ammonium hydroxide (TMAH) may be used to remove the second stopper layer 102 selective to the backside insulating layer 106. A bottom surface and a cylindrical outer sidewall segment of each dielectric layer stack 150′ can be physically exposed.

Subsequently, the bottom portion of each memory opening fill structure 58 can be removed. Referring to FIG. 19B, a sequence of isotropic etch processes may be performed to sequentially etch the various component layers of each dielectric layer stacks 150′. Within each memory opening fill structure 58, the outer dielectric layer 152 and the blocking dielectric layer 52 may comprise silicon oxide, the intermediate dielectric layer 154 and the memory material layer 54 may comprise silicon nitride, and the inner dielectric layer 156 and the dielectric liner 56 may comprise silicon oxide or a respective ONO stack. In this case, a first wet etch process employing dilute hydrofluoric acid can be performed to etch physically exposed portions of the outer dielectric layer 152, a second wet etch process employing hot phosphoric acid may be performed to etch physically exposed portions of the memory material layer 54, and a third wet etch process employing a mixture of hydrofluoric acid and optionally ammonium fluoride (i.e., buffered oxide etch) may be performed to etch physically exposed portions of the inner dielectric layer 156.

The remaining portion of the dielectric layer stack 150′ has a cylindrical configuration, and is herein referred to as a cylindrical dielectric layer stack 150. The cylindrical dielectric layer stack 150 has a same set of materials as the memory films 50. For example, the cylindrical dielectric layer stack 150 may comprise, from outside to inside, an outer dielectric layer 152 having the same material composition and the same thickness as a blocking dielectric layer 52, an intermediate dielectric layer 154 having the same material composition and the same thickness as a memory material layer 54, and an inner dielectric layer 156 having the same material composition and the same thickness as a dielectric liner 56 (which may be a tunneling dielectric layer). In one embodiment, the backside insulating layer 106 underlies the alternating stack (32, 46) of insulating layers 32 and electrically conductive layers 46. Each memory opening fill structure 58 comprises a cylindrical dielectric layer stack 150 having a same set of materials as the memory film 50 and laterally surrounded by the backside insulating layer 106.

Referring to FIG. 19C, a selective etch process can be performed to etch physically exposed portions of each vertical semiconductor channel 60 selective to the material of the backside gate dielectric layers 57. For example, a wet etch process employing TMY or TMAH may be performed to remove physically exposed portions of the vertical semiconductor channels 60. Each of the backside gate electrodes 22 may have a respective bottom surface that is located below the horizontal plane including the bottom surface of the backside insulating layer 106. The bottom surfaces of the backside gate electrodes 22 may be covered by the backside gate dielectric layer 57. In one embodiment, each remaining portion of the vertical semiconductor channel 60 may comprise a physically exposed annular bottom surface.

Referring to FIG. 19D, a dielectric material layer 107L can be conformally deposited on the physically exposed surfaces of each memory opening fill structure and on the bottom surface of the backside insulating layer 106. The exemplary structure may be flipped upside down to deposit the dielectric material layer 107L. The dielectric material layer 107L comprises a dielectric material such as silicon oxide. The thickness of the dielectric material layer 107L is greater than the lateral thickness of each vertical semiconductor channel 60 (i.e., the lateral distance between an inner cylindrical sidewall and an outer cylindrical sidewall). In one embodiment, the thickness of the dielectric material layer 107L may be the same as, or may be greater than, the sum of the thickness of the memory film 50 and the thickness of the vertical semiconductor channel 60.

Referring to FIG. 19E, an anisotropic etch process can be performed while the exemplary structure is flipped upside down, i.e., while the exemplary structure is oriented such that the dielectric material layer 107L overlies the alternating stack (32, 46). The anisotropic etch process can remove horizontally-extending portions of the dielectric material layer 107L and horizontally-extending end portions of the backside gate dielectric layers 57. Remaining portion of the dielectric material layer 107L comprise annular dielectric spacers 107 laterally surrounding an end portion of a respective backside gate electrode 22.

In summary, an annular dielectric spacer 107 can be formed around a bottom portion of each backside gate electrode 22 on an annular bottom surface of the remaining portion of a respective vertical semiconductor channel 60. The bottom surface of the backside gate electrode 22 can be physically exposed after the anisotropic etch process. In one embodiment, each annular dielectric spacer 107 laterally surrounds a bottom portion of the backside gate electrode 22 and contacts an annular bottom surface of a cylindrical dielectric layer stack 150. In one embodiment, each annular dielectric spacer 107 laterally surrounds a bottom portion of a respective backside gate electrode 22, and is laterally spaced from the backside gate electrode 22 by a backside gate dielectric layer 57.

Referring to FIGS. 19F and 20, at least one electrically conductive material, such as at least one metallic material, may be deposited on the physically exposed end surfaces (i.e., bottom surfaces) of the backside gate electrodes 22, and can be patterned to form a backside electrode contact layer 108. In one embodiment, each bottom surface of the backside gate electrodes 22 may be contacted by the backside electrode contact layer 108. The backside electrode contact layer 108 can be formed directly on a backside surface (i.e., the bottom surface) of the backside insulating layer 106. In one embodiment, the backside electrode contact layer 108 may be vertically spaced from the vertical semiconductor channels 60 by the annular dielectric spacers 107 upon formation of the backside electrode contact layer 108. In one embodiment, each annular dielectric spacer 107 may comprise an outer sidewall having a convex vertical cross-sectional profile and contacting a vertically-concave surface segment of the backside electrode contact layer 108.

In one embodiment, each backside gate electrode 22 is laterally surrounded by a respective vertical semiconductor channel 60, and is spaced from the respective vertical semiconductor channel 60 by a respective backside gate dielectric layer 57. The bottom surface of each backside gate electrode 22 may be located below a horizontal plane including the bottom surface (i.e., the backside surface) of the backside insulating layer 106. The backside insulating layer 106 laterally surrounds the bottom portion of each memory opening fill structure 58, and is located between the source layer 110 and the backside electrode contact layer 108. The backside electrode contact layer 108 may be in contact with each backside gate electrode 22, and may be vertically spaced from the alternating stack (32, 46) by the backside insulating layer 106 and the source layer 110. A bottom surface of each backside gate electrode 22 may contact a horizontal surface segment of the backside electrode contact layer 108.

Referring to all drawings and according to various embodiments of the present disclosure, a memory device comprises: an alternating stack (32, 46) of insulating layers 32 and electrically conductive layers 46; a memory opening 49 vertically extending through the alternating stack (32, 46); a memory opening fill structure 58 located in the memory opening 49 and comprising a vertical stack of memory elements located at levels of the electrically conductive layers 46 and a vertical semiconductor channel 60; a source layer 110 contacting an outer sidewall of the vertical semiconductor channel 60; a backside gate electrode 22 laterally surrounded by the vertical semiconductor channel 60 and spaced from the vertical semiconductor channel 60 by a backside gate dielectric layer 57; and a backside electrode contact layer 108 in contact with the backside gate electrode 22 and vertically spaced from the alternating stack (32, 46) by the source layer 110.

In one embodiment, the memory device further comprises a backside insulating layer 106 located between the source layer 110 and the backside electrode contact layer 108. In one embodiment, the backside electrode contact layer 108 is also vertically spaced from the alternating stack (32, 46) by the backside insulating layer 106, and a bottom surface of the backside gate electrode 22 contacts a horizontal surface segment of the backside electrode contact layer 108.

In one embodiment, the memory device further comprises an annular dielectric spacer 107 laterally surrounding a bottom portion of the backside gate electrode 22 and laterally spaced from the backside gate electrode 22 by the backside gate dielectric layer 57. In one embodiment, the annular dielectric spacer 107 comprises an outer sidewall having a convex vertical cross-sectional profile and contacting a vertically-concave surface segment of the backside electrode contact layer 108.

In one embodiment, the backside insulating layer 106 laterally surrounds a bottom portion of the memory opening fill structure 58, and a bottom surface of the backside gate electrode 22 is located below a horizontal plane including a bottom surface of the backside insulating layer 106.

In one embodiment, the memory opening fill structure 58 comprises a memory film 50 that laterally surrounds the vertical semiconductor channel 60; the memory film 50 comprises a memory material layer 54; and the vertical stack of memory elements comprises portions of the memory material layer 54 that are located at levels of the electrically conductive layers 46. In one embodiment, the memory film 50 comprises a layer stack including, from outside to inside, a blocking dielectric layer 52, the memory material layer 54, and a tunneling dielectric layer 56.

In one embodiment, the source layer 110 comprises: a source contact layer 114 in contact with a cylindrical surface segment of the outer sidewall of the vertical semiconductor channel 60; and an upper source-level semiconductor layer 116 contacting a top surface of the source contact layer 114 and contacting a first cylindrical surface segment of the memory film 50. In one embodiment, the source layer 110 also comprises a lower source-level semiconductor layer 112 contacting a bottom surface of the source contact layer 114 and contacting a cylindrical surface segment of each dielectric layer stack 150′.

In one embodiment, the memory device comprises a backside insulating layer 106 underlying the alternating stack (32, 46), wherein the memory opening fill structure 58 comprises a cylindrical dielectric layer stack 150 having a same set of materials as the memory film 50 and laterally surrounding the backside insulating layer 106. In one embodiment, the memory device further comprises an annular dielectric spacer 107 laterally surrounding a bottom portion of the backside gate electrode 22 and contacting an annular bottom surface of the cylindrical dielectric layer stack 150.

In one embodiment, the memory device also comprises a dielectric core 62 laterally surrounded by the backside gate dielectric layer 57 and contacting a top surface of the backside gate electrode 22. In one embodiment, the memory device also comprises a drain region 63 that is located above the dielectric core 62 and the backside gate dielectric layer 57, and in contact with an end portion of the vertical semiconductor channel 60, wherein the drain region 60 is electrically isolated from the backside gate electrode 22 by the dielectric core 62.

In one embodiment, the backside gate electrode 22 vertically extends through a predominant subset of the electrically conductive layers 46 that comprises word lines and source side select gate electrodes, and that excludes a topmost electrically conductive layer 46 among the electrically conductive layers 46; and the dielectric core 62 vertically extends through the topmost electrically conductive layer 46 that comprises the drain side select gate electrode.

During the manufacturing sequence, the substrate 9 can be removed through a combination of processing steps in a manner that minimizes collateral damages to the vertical semiconductor channels while exposing bottom surfaces of the backside gate electrodes 22. The selective removal of the various layers during exposure of the bottom surfaces of the backside gate electrodes 22 enhances reliability of the memory opening fill structures 58. Each memory opening fill structure 58 is patterned through a series of isotropic etch processes that selectively remove bottom portions of the dielectric layer stacks 150′ and the backside gate dielectric layers 57 while forming the annular dielectric spacers 107. The annular dielectric spacers 107 provide electrical isolation between the vertical semiconductor channels 60 and the backside electrode contact layer 108.

The backside gate electrodes 22 enhance device characteristics of the NAND strings including the memory opening fill structures 58 applying a backside voltage from the backside to each vertical semiconductor channel 60. The backside bias voltage for the vertical semiconductor channels 60 in the NAND strings may be advantageously employed to enhance charge retention, reduce read disturbance, and improve the threshold voltage distribution across the memory cells.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers;
a memory opening vertically extending through the alternating stack;
a memory opening fill structure located in the memory opening and comprising a vertical stack of memory elements located at levels of the electrically conductive layers and a vertical semiconductor channel;
a source layer contacting an outer sidewall of the vertical semiconductor channel;
a backside gate electrode laterally surrounded by the vertical semiconductor channel and spaced from the vertical semiconductor channel by a backside gate dielectric layer; and
a backside electrode contact layer in contact with the backside gate electrode and vertically spaced from the alternating stack by the source layer.

2. The memory device of claim 1, further comprising a backside insulating layer located between the source layer and the backside electrode contact layer.

3. The memory device of claim 2, wherein the backside electrode contact layer is also vertically spaced from the alternating stack by the backside insulating layer, and a bottom surface of the backside gate electrode contacts a horizontal surface segment of the backside electrode contact layer.

4. The memory device of claim 2, further comprising an annular dielectric spacer laterally surrounding a bottom portion of the backside gate electrode and laterally spaced from the backside gate electrode by the backside gate dielectric layer.

5. The memory device of claim 4, wherein the annular dielectric spacer comprises an outer sidewall having a convex vertical cross-sectional profile and contacting a vertically-concave surface segment of the backside electrode contact layer.

6. The memory device of claim 2, wherein:
the backside insulating layer laterally surrounds bottom portion of the memory opening fill structure; and
a bottom surface of the backside gate electrode is located below a horizontal plane including a bottom surface of the backside insulating layer.

7. The memory device of claim 2, wherein:
the memory opening fill structure comprises a memory film that laterally surrounds the vertical semiconductor channel;
the memory film comprises a memory material layer; and
the vertical stack of memory elements comprises portions of the memory material layer that are located at levels of the electrically conductive layers.

8. The memory device of claim 7, wherein the memory film comprises a layer stack including, from outside to inside, a blocking dielectric layer, the memory material layer, and a tunneling dielectric layer.

9. The memory device of claim 7, wherein the source layer comprises:
a source contact layer in contact with a cylindrical surface segment of the outer sidewall of the vertical semiconductor channel; and
an upper source-level semiconductor layer contacting a top surface of the source contact layer and contacting a cylindrical surface segment of the memory film.

10. The memory device of claim 7, wherein the memory opening fill structure comprises a cylindrical dielectric layer stack having a same set of materials as the memory film and laterally surrounded by the backside insulating layer.

11. The memory device of claim 10, further comprising an annular dielectric spacer laterally surrounding a bottom portion of the backside gate electrode and contacting an annular bottom surface of the cylindrical dielectric layer stack.

12. The memory device of claim 1, further comprising a dielectric core laterally surrounded by the backside gate dielectric layer and contacting a top surface of the backside gate electrode.

13. The memory device of claim 12, further comprising a drain region that is located above the dielectric core and the backside gate dielectric layer and in contact with an end portion of the vertical semiconductor channel, wherein the drain region is electrically isolated from the backside gate electrode by the dielectric core.

14. The memory device of claim 12, wherein:
the backside gate electrode vertically extends through a predominant subset of the electrically conductive layers that comprises word lines and source side select gate electrodes, and excludes a topmost electrically conductive layer of the electrically conductive layers that comprises a drain side select gate electrode; and
the dielectric core vertically extends through the topmost electrically conductive layer that comprises the drain side select gate electrode.

15. A method of forming a device structure, comprising:
forming a source-level sacrificial layer and an alternating stack of insulating layers and sacrificial material layers over a substrate;
a memory opening through the alternating stack and the source-level sacrificial layer;
forming a memory opening fill structure in the memory opening, wherein the memory opening fill structure comprises, from outside to inside and in an order of formation, a memory film, a vertical semiconductor channel, a backside gate dielectric layer; and a backside gate electrode;
replacing the source-level sacrificial layer with a source contact layer such that the source contact layer contacts an outer sidewall of the vertical semiconductor channel; and
replacing the sacrificial material layers with electrically conductive layers.

16. The method of claim 15, further comprising:
removing the substrate after formation of the electrically conductive layers; and
forming a backside electrode contact layer on a bottom surface of the backside gate electrode.

17. The method of claim 16, further comprising forming a backside insulating layer on a top surface of the substrate, wherein:
the source-level sacrificial layer is formed above the backside insulating layer;
the memory opening vertically extends through the backside insulating layer; and
the backside electrode contact layer is formed on a backside surface of the backside insulating layer.

18. The method of claim 16, further comprising:
removing a bottom portion of the memory opening fill structure after removing the substrate, wherein a remaining portion of the vertical semiconductor channel comprises an annular bottom surface;
physically exposing a bottom surface of the backside gate electrode; and
forming an annular dielectric spacer around a bottom portion of the backside gate electrode on the annular bottom surface of the remaining portion of the vertical semiconductor channel.

19. The method of claim 18, wherein the backside electrode contact layer is vertically spaced from the remaining portion of the vertical semiconductor channel by the annular dielectric spacer.

20. The method of claim 15, wherein the memory opening fill structure further comprises:
a dielectric core that is surrounded by the backside gate dielectric layer, and located on a top surface of the backside gate electrode; and
a drain region that is located above the dielectric core and the backside gate dielectric layer and in contact with an end portion of the vertical semiconductor channel, wherein the drain region is electrically isolated from the backside gate electrode by the dielectric core.
